(19) United States
(12) Patent Application Publication
(10) Pub. No.: US 2017/0170029 A1
(43) Pub. Date: Jun. 15, 2017

(54) THIN FILM TRANSISTOR

(71) Applicant: KABUSHIKI KAISHA KOBE SEIKO SHO(KOBE STEEL, LTD.), Kobe-shi (JP)

(72) Inventors: Mototaka OCHI, Kobe-shi (JP); Yasuyuki TAKANASHI, Kobe-shi (JP); Aya MIKI, Kobe-shi (JP); Hiroshi GOTO, Kobe-shi (JP); Toshihiro KUGIMIYA, Kobe-shi (JP)

(73) Assignee: KABUSHIKI KAISHA KOBE SEIKO SHO(KOBE STEEL, LTD.), Kobe-shi (JP)

(21) Appl. No.: 15/327,296

(22) PCT Filed: Aug. 6, 2015
(86) PCT No.: PCT/JP2015/072326

§ 371 Date: Jan. 18, 2017

(30) Foreign Application Priority Data
Sep. 2, 2014 (JP) 2014-178587
Dec. 3, 2014 (JP) 2014-245124
Jul. 1, 2015 (JP) 2015-132533

(51) Int. Cl. H01L 21/467; C23C 14/34; H01L 29/04; C23C 14/18; H01L 21/02; H01L 29/786; C23C 14/08; C23C 14/35

(52) U.S. Cl. CPC H01L 21/467; C23C 14/08; C23C 14/3464; C23C 14/35; C23C 14/18; H01L 21/02631; H01L 21/02565; H01L 29/7869; H01L 29/78696; H01L 29/04; H01L 21/0259; H01L 29/78618; H01L 21/02667

(57) ABSTRACT

This thin film transistor has a gate electrode, a gate insulating film, an oxide semiconductor thin film, an etch stop layer for protecting the oxide semiconductor thin film, a source and drain electrodes, and a passivation film in this order on a substrate. The oxide semiconductor thin film is formed of an oxide configured from In, Ga and Sn as metal elements, and O, and has an amorphous structure, and the etch stop layer and/or the passivation film includes SiNx. The thin film transistor has an extremely high mobility of approximately 40 cm²/Vs or more.

### TECHNICAL FIELD

The present invention relates to a thin film transistor including an oxide semiconductor thin film. The thin film transistor of the present invention is suitably used for display devices such as liquid crystal displays and organic EL displays. Hereafter, the thin film transistor may be referred to as a TFT.

### BACKGROUND ART

Amorphous oxide semiconductors have higher carrier mobility than general-purpose amorphous silicon. Amorphous oxide semiconductors also have a large optical band gap and can be formed at a low temperature. Therefore, amorphous oxide semiconductors are promising for use in, for example, next-generation displays required to have a large size and high resolution and operate at a high speed and resin substrates with a low thermal resistance.

When such oxide semiconductors are used for semiconductor layers of TFTs, such oxide semiconductors are required to have good switching characteristics of TFTs. Specific examples of the required switching characteristics include (1) a high on-state current, i.e., a maximum drain current flowing when a positive voltage is applied to a gate electrode and a drain electrode is high, (2) a low off-state current, i.e., a drain current flowing when a negative voltage is applied to a gate electrode and a positive voltage is applied to a drain electrode is low, (3) a low S value (subthreshold swing), i.e., a gate voltage required to increase a drain current tenfold is low, (4) a stable threshold voltage, i.e., a voltage at which a drain current starts to flow when a positive voltage is applied to a drain electrode and a positive or negative voltage is applied to a gate electrode does not change over time and is stably maintained, and (5) a high field effect mobility (hereafter may be simply referred to as mobility).

For example, as disclosed in PTL 1 to PTL 3, In—Ga—Zn amorphous oxide semiconductors (IGZO) constituted by indium, gallium, zinc, and oxygen are well-known as the above oxide semiconductors. However, TFTs produced using the above oxide semiconductors have a field effect mobility of 10 cm²/Vs or less. To address recent demands for display devices, such as larger screen size, higher definition, and higher-speed operation, materials for achieving higher mobility have been required.

### CITATION LIST

### Patent Literature

PTL 1: Japanese Unexamined Patent Application Publication No. 2010-219538

PTL 2: Japanese Unexamined Patent Application Publication No. 2011-174134

PTL 3: Japanese Unexamined Patent Application Publication No. 2013-249537

### SUMMARY OF INVENTION

### Technical Problem

In view of the foregoing, it is an object of the present invention to provide a thin film transistor having a very high mobility of about 40 cm²/Vs or more.

### Solution to Problem

A thin film transistor according to the present invention that has achieved the above object includes a gate electrode, a gate insulating film, an oxide semiconductor thin film, an etch stop layer for protecting the oxide semiconductor thin film, a source/drain electrode, and a passivation film on a substrate in this order. The oxide semiconductor thin film is formed of an oxide constituted by metal elements of In, Ga, and Sn and O and has an amorphous structure, and an atomic ratio of each of the metal elements relative to all the In, Ga, and Sn satisfies formulae (1) to (3) below. At least one of the etch stop layer and the passivation film contains SiNx.

0.30≦In/(In+Ga+Sn)≦0.50 (1)

0.20≦Ga/(In+Ga+Sn)≦0.30 (2)

0.25≦Sn/(In+Ga+Sn)≦0.45 (3)

Hereafter, a thin film transistor containing SiNx only in the passivation film may be referred to as a first thin film transistor (TFT). A thin film transistor containing SiNx only in the etch stop layer and a thin film transistor containing SiNx in both the etch stop layer and the passivation film may be referred to as a second thin film transistor (TFT).

In a preferred embodiment of the present invention, at least part of the oxide semiconductor thin film is crystallized.

In a preferred embodiment of the present invention, the passivation film contains SiNx, and both ends of the oxide semiconductor thin film in a channel length direction and in a channel width direction are in contact with the etch stop layer.

### Advantageous Effects of Invention

According to the present invention, there can be provided a TFT having a very high mobility of about 40 cm²/Vs or more.

### BRIEF DESCRIPTION OF DRAWINGS

FIG. 1 is a schematic sectional view for describing a first thin film transistor according to the present invention.

FIG. 2 is a schematic sectional view for describing a known thin film transistor.

FIG. 3 illustrates Id-Vg characteristics of No. 1-1 in Table 1.

FIG. 4 illustrates a TEM observation result of a cross-section of an oxide semiconductor thin film of No. 1-1 in Table 1.

FIG. 5 illustrates TEM observation results of cross-sections of an oxide semiconductor thin film from the completion of formation of an In—Ga—Sn oxide semiconductor thin film to the completion of a TFT.

FIG. 6 illustrates TEM observation results of surfaces of an oxide semiconductor thin film after formation of an In—Ga—Zn oxide semiconductor thin film and after pre-annealing.

FIG. 7 illustrates TEM observation results of surfaces of an oxide semiconductor thin film after formation of an In—Ga—Zn oxide semiconductor thin film and after pre-annealing.

FIG. 8 illustrates results of X-ray diffraction measurement of In—Ga—Sn oxide semiconductor thin films.

FIG. 9 includes schematic plan views of TFTs having patterns (i) to (iv) in Example 2.

FIG. 10 includes sectional views taken along line A-A′ of FIG. 9.

FIG. 11 includes sectional views taken along line B-B′ of FIG. 9.

FIG. 12 is a schematic sectional view for describing a second thin film transistor according to the present invention.

FIG. 13 includes schematic sectional views illustrating a production process of the second thin film transistor according to the present invention.

FIG. 14 is a schematic sectional view for describing another embodiment of the second thin film transistor according to the present invention.

FIG. 15 includes schematic sectional views for describing a production process of the thin film transistor in FIG. 14.

### DESCRIPTION OF EMBODIMENTS

The present inventors have thoroughly studied to improve the mobility obtained when an In—Ga—Sn oxide containing In, Ga, and Sn as metal elements is used for a semiconductor layer of a TFT. As a result, they have found that, in the oxide semiconductor thin film containing an In—Ga—Sn oxide, this is achieved by appropriately controlling the atomic ratio of each of the metal elements in the In—Ga—Sn oxide and employing at least one of a passivation film containing SiNx and an etch stop layer containing SiNx. Hereafter, the passivation film containing SiNx and the etch stop layer containing SiNx may be collectively referred to as an SiNx-containing layer.

The present inventors have also found the following. The mobility of the TFT is further improved by employing, as an oxide semiconductor thin film, an In—Ga—Sn oxide obtained by crystallizing at least part of the oxide. When the passivation film contains SiNx, the mobility is improved by employing a TFT in which both ends of the oxide semiconductor thin film in a channel length direction and in a channel width direction are in contact with an etch stop layer.

Hereafter, a TFT of the present invention will be described in detail.

First, an oxide semiconductor thin film used in the present invention will be described. The oxide semiconductor thin film is formed of an oxide constituted by metal elements of In, Ga, and Sn and O, and the atomic ratio of each of the metal elements relative to all the In, Ga, and Sn satisfies formulae (1) to (3) below.

0.30≦In/(In+Ga+Sn)≦0.50 (1)

0.20≦Ga/(In+Ga+Sn)≦0.30 (2)

0.25≦Sn/(In+Ga+Sn)≦0.45 (3)

Hereafter, the In content (at %) relative to the total content of In, Ga, and Sn that are all metal elements, which is represented by the formula (1), may be referred to as an In atomic ratio. Similarly, the Ga content (at %) relative to the total content of In, Ga, and Sn that are all metal elements, which is represented by the formula (2), may be referred to as a Ga atomic ratio. Similarly, the Sn content (at %) relative to the total content of In, Ga, and Sn that are all metal elements, which is represented by the formula (3), may be referred to as a Sn atomic ratio.

### In Atomic Ratio

In is an element that contributes to improving electrical conductivity. The increase in the In atomic ratio represented by the formula (1), that is, the increase in the amount of In in the metal elements improves the conductivity of the oxide semiconductor thin film, which increases the mobility. To effectively produce the above effect, the In atomic ratio needs to be 0.30 or more. The In atomic ratio is preferably 0.31 or more, more preferably 0.35 or more, and further preferably 0.40 or more. However, if the In atomic ratio is excessively increased, for example, the carrier density excessively increases and thus the threshold voltage decreases. Therefore, the upper limit of the In atomic ratio is 0.50 or less. The In atomic ratio is preferably 0.48 or less and more preferably 0.45 or less.

### Ga Atomic Ratio

Ga is an element that contributes to reducing oxygen defects and controlling the carrier density. The increase in the Ga atomic ratio represented by the formula (2) produces effects of improving the electrical stability of the oxide semiconductor thin film and suppressing the excessive generation of carriers. To more effectively produce the above effects, the Ga atomic ratio needs to be 0.20 or more. The Ga atomic ratio is preferably 0.22 or more and more preferably 0.25 or more. However, if the Ga atomic ratio is excessively increased, the conductivity of the oxide semiconductor thin film decreases and the mobility tends to decrease. Therefore, the Ga atomic ratio is 0.30 or less and preferably 0.28 or less.

### Sn Atomic Ratio

Sn is an element that contributes to improving resistance to acid etching. The increase in the Sn atomic ratio represented by the formula (3) improves the resistance to an inorganic acid etchant in the oxide semiconductor thin film. To more effectively produce the above effect, the Sn atomic ratio needs to be 0.25 or more. The Sn atomic ratio is preferably 0.30 or more, more preferably 0.31 or more, and further preferably 0.35 or more. However, if the Sn atomic ratio is excessively increased, the mobility of the oxide semiconductor thin film decreases and the resistance to an inorganic acid etchant increases more than necessary, which makes it difficult to process the oxide semiconductor thin film itself. Therefore, the Sn atomic ratio is 0.45 or less, preferably 0.40 or less, and more preferably 0.38 or less.

The oxide semiconductor thin film for TFTs normally has an amorphous structure, but at least part of the oxide semiconductor thin film is preferably crystallized (hereafter may be referred to as “having a microcrystalline structure”). If at least part of the oxide semiconductor thin film is crystallized, the mobility of TFTs is considerably increased. Herein, the crystallinity of the oxide semiconductor thin film is not particularly limited as long as an excellent effect of improving the mobility is effectively produced by using a TFT including the oxide semiconductor thin film. The microcrystalline structure of the oxide semiconductor thin film of the present invention can be confirmed by, for example, observing an electron diffraction pattern described later. Although the details are described in Examples, diffraction spots appear more clearly with increasing the ratio of the crystalline structure.

The crystallization of the oxide semiconductor thin film increases the mobility, but decreases an etching rate in a wet etching process and generates a residue, for example. As a result, the productivity and yield are reduced. Therefore, a part of the oxide semiconductor thin film of the present invention is preferably crystallized, which suppresses the decrease in an etching rate in a wet etching process and the generation of a residue. Thus, both the processability of the wet etching process and high mobility in TFTs can be achieved.

The oxide semiconductor thin film having a microcrystalline structure is obtained as follows. In a TFT formation process, when an oxide semiconductor thin film is formed, the gas pressure is controlled to 1 to 5 mTorr. After formation of an SiNx-containing layer, heat treatment (post-annealing) is performed at a temperature of 200° C. or higher. Other conditions in the TFT formation process are not particularly limited, and typical methods can be employed.

First, an oxide semiconductor thin film is formed by controlling the gas pressure to 1 to 5 mTorr. At a gas pressure of less than 1 mTorr, a sufficient film density is not achieved. The lower limit of the gas pressure is preferably 2 mTorr or more. At a gas pressure of more than 5 mTorr, a desired microcrystalline structure is not formed. The upper limit of the gas pressure is preferably 4 mTorr or less and more preferably 3 mTorr or less.

The oxygen concentration in an atmosphere gas is preferably 1 to 40 vol % and more preferably 2 to 30 vol %.

The atmosphere preferred when the oxide semiconductor thin film is formed is an air atmosphere or a water vapor atmosphere.

It is also important that the TFT of the present invention includes an SiNx-containing layer. It has been found from studies conducted by the present inventors that when a TFT including an oxide semiconductor thin film having a particular composition and an SiNx-containing layer is used, hydrogen contained in the SiNx-containing layer diffuses into the oxide semiconductor thin film, which considerably contributes to achieving high mobility. Such an improvement in mobility has been found when the TFT of the present invention is used. It is described in Examples below that such an improvement in mobility is not achieved, for example, when IGZO described in PTL 1 is used.

The amount of hydrogen in the SiNx-containing layer is preferably 20 to 50 at % and more preferably 30 to 40 at %. The amount of hydrogen in the SiNx-containing layer can be controlled by adjusting, for example, the mixing ratio of SiH₄ gas and NH₃ gas and the film formation temperature.

Furthermore, in the present invention, heat treatment is performed at a temperature of 200° C. or higher after the formation of the SiNx-containing layer. Specifically, the heat treatment may be performed after an etch stop layer containing SiNx is formed or after a passivation film containing SiNx is formed. Alternatively, an etch stop layer containing SiNx is formed, the heat treatment is performed, and then a passivation film containing SiNx is formed, and the heat treatment may be performed again. At a heat treatment temperature of lower than 200° C., high mobility of the TFT is not achieved. The lower limit of the heat treatment temperature is preferably 250° C. or higher and more preferably 260° C. or higher. However, if the heat treatment temperature is excessively high, the TFT is made conductive. Therefore, the upper limit of the heat treatment temperature is preferably 280° C. or lower and more preferably 270° C. or lower.

In this heat treatment, the heat treatment time is preferably controlled to 30 to 90 minutes to achieve a desired microcrystalline structure. The atmosphere is not particularly limited, and is, for example, a nitrogen atmosphere or an air atmosphere.

The TFT of the present invention preferably has a structure in which both ends of the oxide semiconductor thin film in a channel length direction and a channel width direction (hereafter may be simply referred to as both ends) are in contact with the etch stop layer. Thus, the mobility of the TFT is considerably increased to about 40 cm²/Vs or more compared with the general-purpose In—Ga—Zn oxide semiconductor thin films described in PTL 1 to PTL 3, for example.

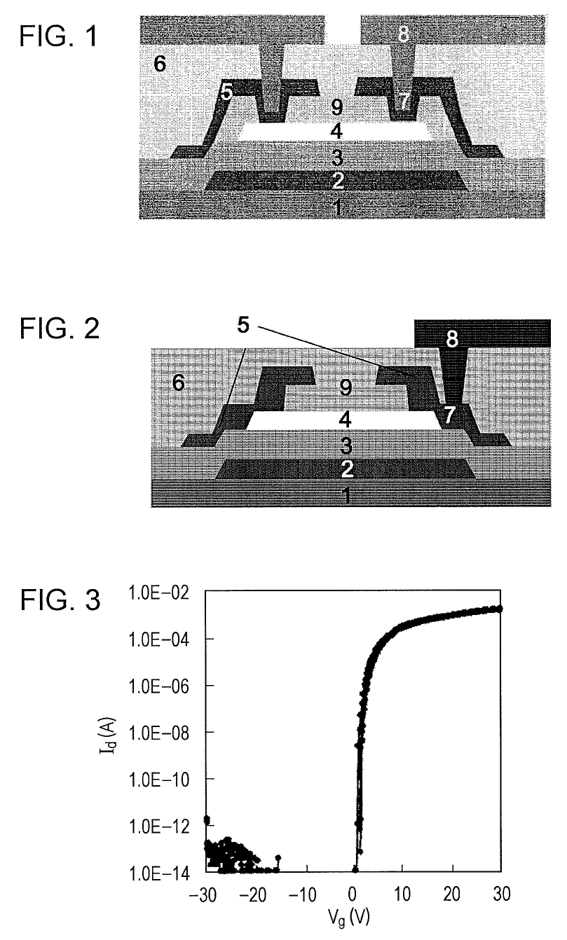

A preferred embodiment of a first TFT having the above structure according to the present invention will be described in detail with reference to FIG. 1. FIG. 2 illustrates a structure of a known TFT for comparison. The configuration of the first TFT according to the present invention is not limited to that in FIG. 1.

As illustrated in FIG. 1, the first TFT according to the above embodiment includes a gate electrode 2, a gate insulating film 3, an oxide semiconductor thin film 4, an etch stop layer 9 for protecting the oxide semiconductor thin film 4, a source/drain electrode 5, and a passivation film 6 on a substrate 1 in this order. Transparent conductive films 8 are electrically connected to the source/drain electrode 5 through contact holes 7. The first TFT according to the above embodiment includes an oxide semiconductor thin film 4 having the above-described composition and microcrystalline structure. The known TFT illustrated in FIG. 2 also has the same order of configuration, except that an In—Ga—Zn oxide semiconductor thin film having an amorphous structure is used as the oxide semiconductor thin film 4.

The first TFT according to the above embodiment has a structure in which both ends of the oxide semiconductor thin film 4 in a channel length direction are in contact with the etch stop layer 9 as illustrated in FIG. 1 (i.e., the etch stop layer 9 is formed so as to cover both ends of the oxide semiconductor thin film 4 in a channel length direction). The known TFT in FIG. 2 has a structure in which both ends of the oxide semiconductor thin film 4 in a channel length direction are in contact with the source/drain electrode 5 (i.e., the source/drain electrode 5 is formed so as to cover both ends of the oxide semiconductor thin film 4 in a channel length direction). The first TFT is totally different from the known TFT in that both ends of the oxide semiconductor thin film 4 in a channel length direction are not in contact with the source/drain electrode 5. Focusing on the upper surface of the oxide semiconductor thin film 4 in FIGS. 1 and 2, in the invention example in FIG. 1, a part of the etch stop layer 9 is patterned and the upper surface has regions in contact with the contact holes 7 with the source/drain electrode 5 disposed therebetween. On the other hand, in the known example in FIG. 2, the etch stop layer 9 is not patterned and the upper surface does not have regions in contact with the contact holes 7 with the source/drain electrode 5 disposed therebetween. In both FIGS. 1 and 2, both the ends of the oxide semiconductor thin film 4 in the channel length direction are not directly in contact with the passivation film 6.

Hereafter, a preferred method for producing the TFT according to the above embodiment will be described with reference to FIG. 1. The present invention is not limited thereto.

First, a gate electrode 2 and a gate insulating film 3 are formed on a substrate 1. The method for forming the gate electrode 2 and the gate insulating film 3 are not particularly limited, and a typical method can be employed. The types of gate electrode 2 and gate insulating film 3 are also not particularly limited, and general-purpose electrodes and films can be used. For example, the gate electrode 2 is preferably made of a metal with low electrical resistivity, such as Al or Cu, a high-melting-point metal with a high thermal resistance, such as Mo, Cr, or Ti, or an alloy of the foregoing. Examples of the gate insulating film 3 include silicon oxide films, silicon nitride films, and silicon oxynitride films. In addition, an oxide such as Al₂O₃ or Y₂O₃ or a laminate of the oxides can be used.

Subsequently, the above-described oxide semiconductor thin film 4 is formed. As described above, it is important in the present invention that the gas pressure is controlled to 1 to 5 mTorr when the oxide semiconductor thin film is formed, and heat treatment is performed at a temperature of 200° C. or higher after formation of the passivation film. Other processes are not particularly limited, and typical methods can be employed. A preferred method is as follows.

For example, the oxide semiconductor thin film 4 is preferably formed by a sputtering method such as a DC sputtering method or an RF sputtering method using a sputtering target. Hereafter, the sputtering target may be simply referred to as a “target”. By employing a sputtering method, a thin film with a uniform composition and thickness in an in-plane direction of the film can be easily formed. Alternatively, an oxide may be formed by a chemical method for film formation such as a coating method.

The target used in the sputtering method is preferably a target that contains the above-described elements and has the same composition as the desired oxide. By using such a target, a thin film having a desired composition with reduced composition unevenness can be formed. Specifically, a target which is made of an oxide containing In, Ga, and Sn as metal elements and in which the atomic ratio of each metal element relative to all the In, Ga, and Sn satisfies the formulae (1) to (3) is desirably used.

Alternatively, a combinatorial sputtering method in which two targets having different compositions are simultaneously subjected to discharge may also be employed. For example, oxide targets containing one of In, Ga, and Sn, such as In₂O₃, Ga₂O₃, and SnO₂ or oxide targets formed of a mixture containing two or more of the above elements can also be used. Furthermore, film formation may be performed using one or more of pure metal targets and alloy targets containing the above metal elements while oxygen is supplied as an atmosphere gas.

The target can be produced by, for example, a powder sintering method.

When the film formation is performed by a sputtering method using the above target, for example, the partial pressure of oxygen, the input power on the target, the substrate temperature, and the T-S distance, which is a distance between the target and a substrate, are preferably appropriately controlled in addition to the gas pressure during film formation.

Specifically, the film formation is preferably performed, for example, under the following sputtering conditions.

To exhibit semiconductor properties, the amount of oxygen added is preferably controlled so that the carrier density of the oxide semiconductor thin film 4 is 1×10¹⁵ to 10¹⁷/cm³. The amount of oxygen added may be appropriately controlled to an optimum amount in accordance with, for example, a sputtering apparatus, a target composition, and a production process for thin film transistors. In Examples described later, the amount of oxygen added was set so as to satisfy 100×O₂/(Ar+O₂)=4 vol % in terms of addition flow ratio.

The film formation power density is desirably as high as possible, and is desirably set to about 2.0 W/cm² or more in a DC sputtering method or an RF sputtering method. However, an excessively high film formation power density may cause cracking and chipping on the oxide target. Therefore, the upper limit thereof is about 50 W/cm².

The substrate temperature during film formation is desirably controlled to about room temperature to 200° C.

The amount of defects in the oxide semiconductor thin film 4 is also affected by the heat treatment conditions after film formation, and thus the heat treatment conditions are preferably appropriately controlled. The heat treatment after film formation is desirably performed, for example, in an air atmosphere at about 250° C. to 400° C. for 10 minutes to 3 hours. The heat treatment is, for example, pre-annealing treatment (heat treatment performed immediately after the oxide semiconductor thin film 4 having been wet-etched is patterned) described later.

The thickness of the oxide semiconductor thin film 4 is preferably about 10 nm or more and more preferably 20 nm or more, and is preferably 200 nm or less and more preferably 100 nm or less.

After the oxide semiconductor thin film 4 is formed, the oxide semiconductor thin film 4 is patterned by performing wet etching. Immediately after the patterning, heat treatment (pre-annealing treatment) is preferably performed to improve the quality of the oxide semiconductor thin film 4. This improves the transistor performance because the on-state current and field effect mobility of transistor characteristics are increased. The pre-annealing treatment is preferably performed, for example, in a water vapor atmosphere or an air atmosphere at 350° C. to 400° C. for 30 to 60 minutes.

Subsequently, an etch stop layer 9 is formed. The method for forming an etch stop layer 9 is not particularly limited, and a typical method can be employed.

In the first TFT according to this embodiment, an SiNx film is only used for a passivation film 6, and any film typically used in the field of TFTs can be used for the etch stop layer 9. A film such as an SiOxNy (silicon oxynitride) film, an SiOx (silicon oxide) film, an Al₂O₃ film, or a Ta₂O₅ film can be used for the etch stop layer 9. Specifically, the etch stop layer 9 may have a single-layer structure formed of a single film selected from the above films, may have a multilayer structure formed by laminating a plurality of films of the same type selected from the above films, or may have a multilayer structure formed by laminating two or more types of films selected from the above films.

Subsequently, a source/drain electrode 5 is formed. The type of source/drain electrode 5 is not particularly limited, and general-purpose electrodes can be used. For example, the source/drain electrode 5 may be made of a metal such as Al, Mo, or Cu or an alloy as in the case of the gate electrode.

The source/drain electrode 5 can be formed by, for example, forming a metal thin film by a magnetron sputtering method, then performing patterning by photolithography, and performing wet etching.

Before formation of a passivation film 6 described below, heat treatment (200° C. to 300° C.) or N₂O plasma treatment may be optionally performed to remove the damage on the surface of the oxide.

Subsequently, a passivation film 6 is formed above the oxide semiconductor thin film 4 by a CVD (chemical vapor deposition) method.

As described above, it is important in the first TFT according to this embodiment to use a passivation film 6 containing SiNx. The use of the passivation film 6 containing SiNx effectively produces an effect of improving the mobility due to diffusion of hydrogen into the oxide semiconductor thin film 4. The passivation film 6 may be formed by laminating any films other than an SiNx film as long as the passivation film 6 includes the SiNx film. For example, the passivation film 6 may have a single-layer structure formed of a single SiNx film, may have a multilayer structure formed by laminating a plurality of SiNx films, or may have a multilayer structure formed by laminating an SiNx film and at least one film selected from SiOxNy films, SiOx films, Al₂O₃ films, Ta₂O₅ films, and the like. For example, the passivation film 6 preferably has a multilayer structure including an SiNx film as an upper layer and an SiOx film as a lower layer as described in Examples below.

The thickness of the SiNx film in the passivation film 6 is preferably 50 to 400 nm and more preferably 100 to 200 nm. In the case of a passivation film 6 including a plurality of SiNx films laminated on top of each other, the thickness of the SiNx film indicates the total thickness of all the SiNx films. The proportion of the thickness of the SiNx film relative to the total thickness of the passivation film 6 is preferably 20% to 100% and more preferably 40% to 70%.

Subsequently, contact holes 7 used for probing for evaluating transistor characteristics are formed in the passivation film 6. Then, the post-annealing described above is performed.

Subsequently, transparent conductive films 8 are electrically connected to the source/drain electrode 5 through the contact holes 7 by a typical method. The type of transparent conductive film 8 is not particularly limited, and typical films can be used.

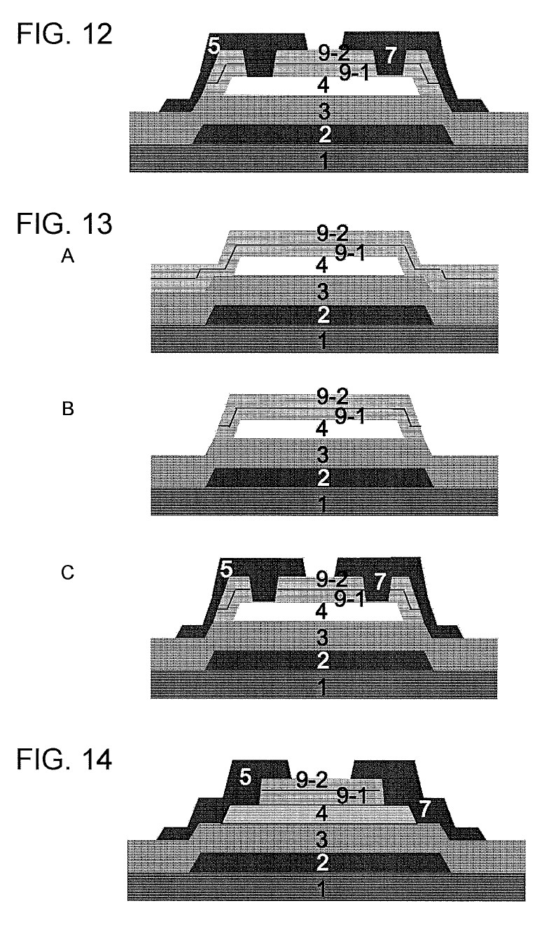

Hereafter, a preferred embodiment of a second TFT according to the present invention will be described in detail with reference to FIG. 12 to FIG. 15. The configuration of the second TFT according to the present invention is not limited to those illustrated in FIG. 12 to FIG. 15. The processes performed until the oxide semiconductor thin film 4 is formed are the same as those described in the first TFT, and the description thereof is omitted.

After the formation of the oxide semiconductor thin film 4, an etch stop layer 9 is formed. The method for forming the etch stop layer 9 is not particularly limited, and a typical method can be employed. It is important in the second TFT according to this embodiment to use an etch stop layer 9 containing SiNx. The use of the etch stop layer 9 containing SiNx effectively produces an effect of improving the mobility due to diffusion of hydrogen into the oxide semiconductor thin film 4. The etch stop layer 9 may be formed by laminating any films other than an SiNx film as long as the etch stop layer 9 includes the SiNx film. That is, the etch stop layer 9 may have a single-layer structure formed of a single SiNx film or may have a multilayer structure formed by laminating a plurality of SiNx films. For example, the etch stop layer 9 may have a multilayer structure formed by laminating an SiNx film and at least one film selected from SiOxNy films, SiOx films, Al₂O₃ films, Ta₂O₅ films, and the like. Alternatively, the etch stop layer 9 may have a multilayer structure including an SiNx film 9-2 as an upper layer and an SiOx film 9-1 as a lower layer as described in Examples below.

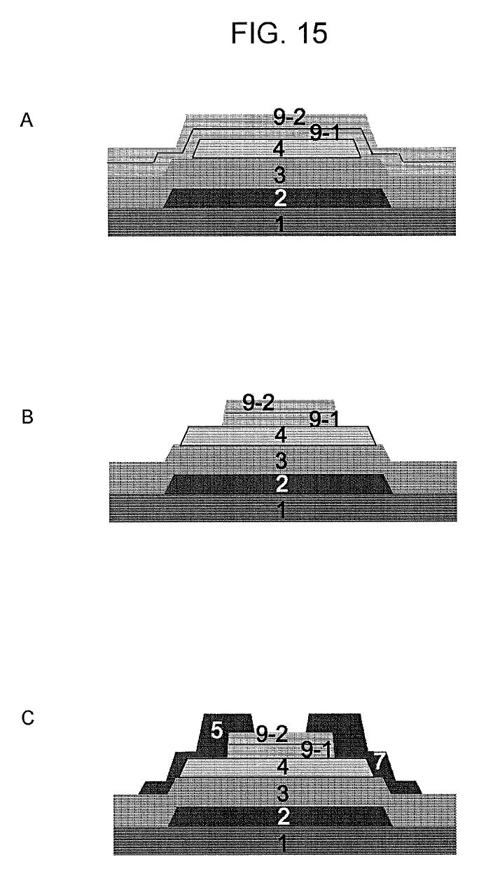

In the second TFT according to this embodiment, both ends of the oxide semiconductor thin film 4 may be in contact with the etch stop layer 9 as illustrated in FIG. 12 and FIG. 13, or may be not in contact with the etch stop layer 9 as illustrated in FIG. 14 and FIG. 15. In the second TFT according to this embodiment, therefore, the etch stop layer 9 can be disposed only in a channel portion of the oxide semiconductor thin film 4.

The thickness of the SiNx film in the etch stop layer 9 is preferably 50 to 250 nm and more preferably 100 to 200 nm. In the case of an etch stop layer 9 including a plurality of SiNx films laminated on top of each other, the thickness of the SiNx film indicates the total thickness of all the SiNx films. The proportion of the thickness of the SiNx film relative to the total thickness of the etch stop layer 9 is preferably 30% to 100% and more preferably 40% to 80%.

Subsequently, contact holes 7 used for probing for evaluating transistor characteristics are formed in the etch stop layer 9. Then, the post-annealing described above is performed. As long as the etch stop layer 9 is formed, the post-annealing may be performed before formation of a source/drain electrode 5 described below or after formation of the source/drain electrode 5.

Subsequently, a source/drain electrode 5 is formed. The type of source/drain electrode 5 is not particularly limited, and general-purpose electrodes can be used. For example, the source/drain electrode 5 may be made of a metal such as Al, Mo, or Cu or an alloy as in the case of the gate electrode.

The source/drain electrode 5 can be formed by, for example, forming a metal thin film by a magnetron sputtering method, then performing patterning by photolithography, and performing wet etching.

Before formation of a passivation film 6 described below, heat treatment (200° C. to 300° C.) or N₂O plasma treatment may be optionally performed to remove the damage on the surface of the oxide.

Subsequently, a passivation film 6 may be formed above the oxide semiconductor thin film 4 by a CVD method. Examples of the passivation film 6 in the second TFT according to this embodiment include SiNx films, SiOxNy films, SiOx films, Al₂O₃ films, and Ta₂O₅ films. The passivation film 6 may have a single-layer structure formed of a single film selected from the above films, may have a multilayer structure formed by laminating a plurality of films of the same type selected from the above films, or may have a multilayer structure formed by laminating two or more types of films selected from the above films.

Subsequently, transparent conductive films 8 are electrically connected to the source/drain electrode 5 through the contact holes 7 by a typical method. The type of transparent conductive film 8 is not particularly limited, and typical films can be used.

The thus-produced first and second TFTs according to the present invention have a very high mobility of about 40 cm²/Vs or more, which is determined by Hall measurement that derives mobility from Id-Vg measurement, as described later.

This application claims the benefit of Japanese Patent Application Nos. 2014-178587 filed on Sep. 2, 2014, 2014-245124 filed on Dec. 3, 2014, and 2015-132533 filed on Jul. 1, 2015, the entire contents of which are incorporated herein by reference.

### EXAMPLES

Hereafter, the present invention will be more specifically described based on Examples. The present invention is not limited to Examples below, and can be modified without departing from the spirit described herein. Such variations are within the technical scope of the present invention.

### Example 1

In Example 1 according to the first TFT, the influence of the formation conditions of the oxide semiconductor thin film on the mobility of the TFT was studied. In Example 1, only the passivation film contained SiNx.

First, a Mo thin film serving as a gate electrode 2 with a thickness of 100 nm and a SiO₂ (thickness: 200 nm) serving as a gate insulating film 3 were sequentially formed on a glass substrate 1 (EAGLE 2000 manufactured by Corning, diameter 100 mm×thickness 0.7 mm). The gate electrode 2 was formed by a DC sputtering method using a pure Mo sputtering target. The sputtering was performed under the conditions of film formation temperature: room temperature, film formation power density: 3.8 W/cm², carrier gas: Ar, gas pressure during film formation: 2 mTorr, and Ar gas flow rate: 20 sccm. The gate insulating film 3 was formed by a plasma CVD method under the conditions of carrier gas: mixture gas of SiH₄ and N₂O, film formation power density: 0.96 W/cm², film formation temperature: 320° C., and gas pressure during film formation: 133 Pa.

Subsequently, an oxide semiconductor thin film 4 (In—Ga—Sn—O film, thickness: 40 nm) having the following composition was formed under various sputtering conditions shown in Table 1.

### In:Ga:Sn=42.7:26.7:30.6 at %

Specifically, an oxide semiconductor thin film was formed by a sputtering method under the following conditions using a sputtering target having the same composition as the above oxide semiconductor thin film 4.

Sputtering apparatus: “CS-200” manufactured by ULVAC, Inc.
Substrate temperature: room temperature
Gas pressure: 1, 3, 5, 10 mTorr

### Carrier gas: Ar

Partial pressure of oxygen: 100×O₂/(Ar+O₂)=4, 12, 20 vol %
Film formation power density: 1.27, 2.55, 3.83 W/cm²
Sputtering target used: In:Ga:Sn=42.7:26.7:30.6 at %

The contents of the metal elements in the oxide semiconductor thin film were analyzed using samples separately prepared by forming an oxide semiconductor thin film with a thickness of 40 nm on a glass substrate by a sputtering method in the same manner. The analysis was conducted by ICP (inductively coupled plasma) emission spectroscopy using a CIROS Mark II (manufactured by Rigaku Corporation).

Furthermore, the electrical resistivity was measured as follows using the above samples prepared by forming an oxide semiconductor thin film with a thickness of 40 nm on a glass substrate. Table 1 shows the measurement results. In Table 1 below, “aE+b” refers to “a×10^{b}”.

### Manufacturer: Mitsubishi Chemical Analytech Co., Ltd.

Product name: Hiresta (registered trademark) UP

### Model: MCP-HT450

Measurement method: ring electrode

After the oxide semiconductor thin film 4 was formed as described above, patterning was performed by photolithography and wet etching. The wet etchant was “ITO-07N” manufactured by KANTO CHEMICAL CO., INC. In Example 1, it was confirmed that there was no residue generated as a result of the wet etching and thus the etching was appropriately performed in all the oxide semiconductor thin films used in the experiment.

As described above, after the oxide semiconductor thin film 4 was patterned, pre-annealing was performed to improve the film quality. The pre-annealing was performed in an air atmosphere at 350° C. for 1 hour.

After the pre-annealing, an SiOx film (thickness: 100 nm) serving as an etch stop layer 9 was formed on the oxide semiconductor thin film 4. The SiOx film was formed by a plasma CVD method using a mixture gas of N₂O and SiH₄ under the conditions of film formation power density: 0.32 W/cm², film formation temperature: 230° C., and gas pressure during film formation: 133 Pa. After the formation of the SiOx film, the etch stop layer 9 was patterned by photolithography and dry etching.

Subsequently, a pure Mo film with a thickness of 200 nm was formed above the oxide semiconductor thin film 4 by a sputtering method in order to form a source/drain electrode 5. The pure Mo film was formed under the conditions of input power: DC 300 W (film formation power density: 3.8 W/cm²), carrier gas: Ar, gas pressure: 2 mTorr, and substrate temperature: room temperature.

Subsequently, the source/drain electrode 5 was patterned by photolithography and wet etching. Specifically, a mixed acid etchant made of a mixture solution containing phosphoric acid:nitric acid:acetic acid=70:2:10 (mass ratio) at 40° C. was used.

After the source/drain electrode 5 was formed, an SiOx film with a thickness of 100 nm serving as a passivation film 6 for protecting an oxide semiconductor thin film transistor was formed by a plasma CVD method. Furthermore, an SiNx film with a thickness of 150 nm was formed by a plasma CVD method. The SiOx film was formed using a mixture gas of SiH₄, N₂, and N₂O, and the SiNx film was formed using a mixture gas of SiH₄, N₂, and NH₃. Both films were formed under the conditions of film formation power density: 0.32 W/cm², film formation temperature: 150° C., and gas pressure during film formation: 133 Pa.

Subsequently, contact holes 7 used for probing for evaluating transistor characteristics were formed in the passivation film 6 by photolithography and dry etching. Then, heat treatment was performed as post-annealing in a nitrogen atmosphere at 260° C. for 30 minutes.

Finally, ITO films with a thickness of 80 nm were formed as transparent conductive films 8 to produce a thin film transistor in FIG. 1. Specifically, the ITO film was formed by a DC sputtering method under the conditions of carrier gas: mixture gas of argon and oxygen, film formation power: 200 W (film formation power density: 2.5 W/cm²), and gas pressure: 5 mTorr.

The produced thin film transistor had a channel length of 20 μm and a channel width of 200 μm.

The following characteristics were investigated for the TFT.

### (1) Measurement of Transistor Characteristics

The transistor characteristics (drain current-gate voltage characteristics, Id-Vg characteristics) were measured with a semiconductor parameter analyzer “HP4156C” manufactured by Agilent Technology. The specific measurement conditions are as follows. FIG. 3 illustrates the Id-Vg characteristics of No. 1-1 in Table 1.

Source voltage: 0 V
Drain voltage: 10 V
Gate voltage: −30 to 30 V (measurement interval: 0.25 V)
Substrate temperature: room temperature

### (2) Threshold Voltage (Vth)

The threshold voltage is roughly a gate voltage at which the state of a transistor changes from an off-state (low-drain-current state) to an on-state (high-drain-current state). In Example 1, the voltage at which the drain current is about 1 nA between an on-state current and an off-state current was defined as a threshold voltage. The threshold voltage of each of the thin film transistors was measured.

### (3) Field Effect Mobility μFE

The field effect mobility μFE was derived from a relational formula Id=μFE×Cox×W×(Vg−Vth)²/2L between the drain current and the gate voltage in a saturation region that satisfies Vg>Vd−Vth in terms of transistor characteristics (Vg: gate voltage, Vd: drain voltage, Id: drain current, L: channel length, W: channel width, Cox: capacitance of gate insulating film, μFE: field effect mobility). In Example 1, the field effect mobility μFE was derived from a slope of the drain current-gate voltage characteristics (Id-Vg characteristics) near a gate voltage that satisfies a linear region. The field effect mobility is desirably as high as possible. In Example 1, the criterion of the field effect mobility was set to 40 cm²/Vs, and “Good” was given when the field effect mobility was 40 cm²/Vs or more.

### (4) S Value

The S value is a minimum gate voltage required to increase the drain current tenfold in terms of Id-Vg characteristics, and a lower S value exhibits better characteristics. Specifically, the S values were good under all the conditions, which were 0.4 V/decade or less.

Table 1 also shows the results.

TABLE 1

| | Sputtering conditions | | | Thin film | Thin film transistor | | |
|---|---|---|---|---|---|---|---|
| | Partial | | | properties | characteristics | | |
| | pressure | Gas | Film formation | Electrical | | Threshold | |
| | of oxygen | pressure | power density | resistivity | Mobility | voltage | S value |
| No. | (vol %) | (mTorr) | (W/cm²) | (Ωcm) | (cm²/Vs) | (V) | (V/decade) |
| 1-1 | 4 | 1 | 2.55 | 1.05E+01 | 66.2 | 0 to 2 | ≦0.4 |
| 1-2 | 12 | 1 | 2.55 | 3.20E+07 | 42.9 | 0 to 2 | ≦0.4 |
| 1-3 | 20 | 1 | 2.55 | 2.10E+07 | 31.7 | 0 to 2 | ≦0.4 |
| 1-4 | 4 | 3 | 2.55 | 7.20E+03 | 53.1 | 0 to 2 | ≦0.4 |
| 1-5 | 4 | 5 | 2.55 | 1.05E+05 | 42.6 | 0 to 2 | ≦0.4 |
| 1-6 | 4 | 10 | 2.55 | 5.30E+08 | 20.2 | 0 to 2 | ≦0.4 |
| 1-7 | 4 | 1 | 1.27 | 2.70E+01 | 62.2 | 0 to 2 | ≦0.4 |
| 1-8 | 4 | 1 | 3.83 | 1.90E+00 | 75.6 | 0 to 2 | ≦0.4 |

It was found from Table 1 that when the partial pressure of oxygen and the film formation power density were the same, the mobility increased as the gas pressure decreased (refer to Nos. 1-1, 1-4, 1-5, and 1-6 in Table 1). It was also found that when the gas pressure and the film formation power density were the same, the mobility increased as the partial pressure of oxygen decreased under the above experiment conditions (refer to Nos. 1-1 to 1-3 in Table 1). A large influence of the film formation power density on the mobility was not observed.

To evaluate the crystalline structure of the oxide semiconductor thin film, the TEM observation of a cross-section, the observation of an electron diffraction pattern, and X-ray diffraction measurement were performed.

### (TEM Observation of Cross-Section and Electron Diffraction Measurement)

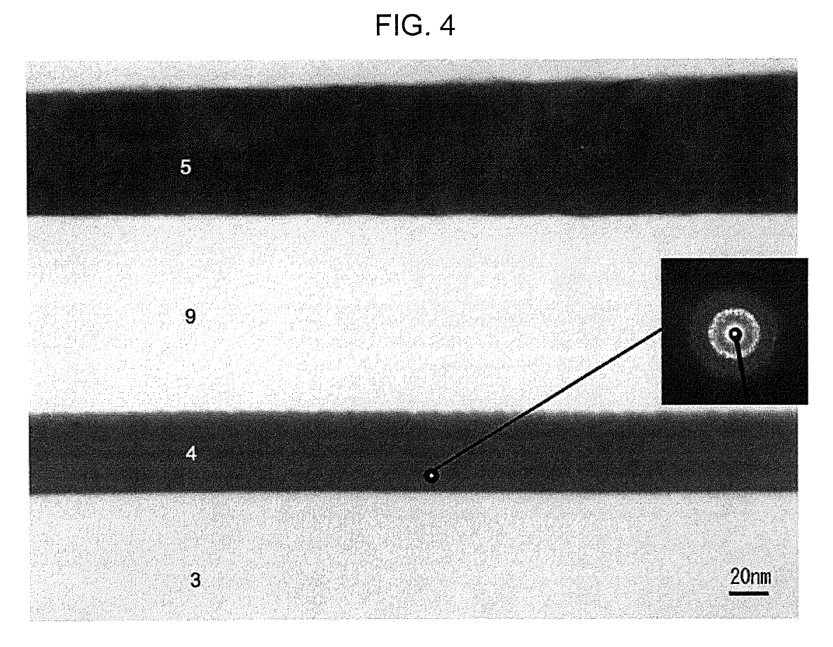

FIG. 4 illustrates the TEM observation result of a cross-section of the oxide semiconductor thin film after the production of the thin film transistor No. 1-1 in Table 1. The electron diffraction pattern in a bright circular region in the oxide semiconductor thin film in FIG. 4 is illustrated on the right side of FIG. 4. There are diffraction spots in the ring diffraction pattern. Such diffraction spots do not clearly appear in an amorphous structure, but the diffraction spots become clearer as the fraction of a crystalline structure in the oxide semiconductor thin film increases. As is clear from FIG. 4, the oxide semiconductor thin film according to the present invention has a crystalline structure.

Next, it will be demonstrated that the crystalline structure of the oxide semiconductor thin film is observed immediately after the oxide semiconductor thin film 4 is formed on the gate insulating film 3, and the crystalline structure does not change so much through the thin film transistor production process.

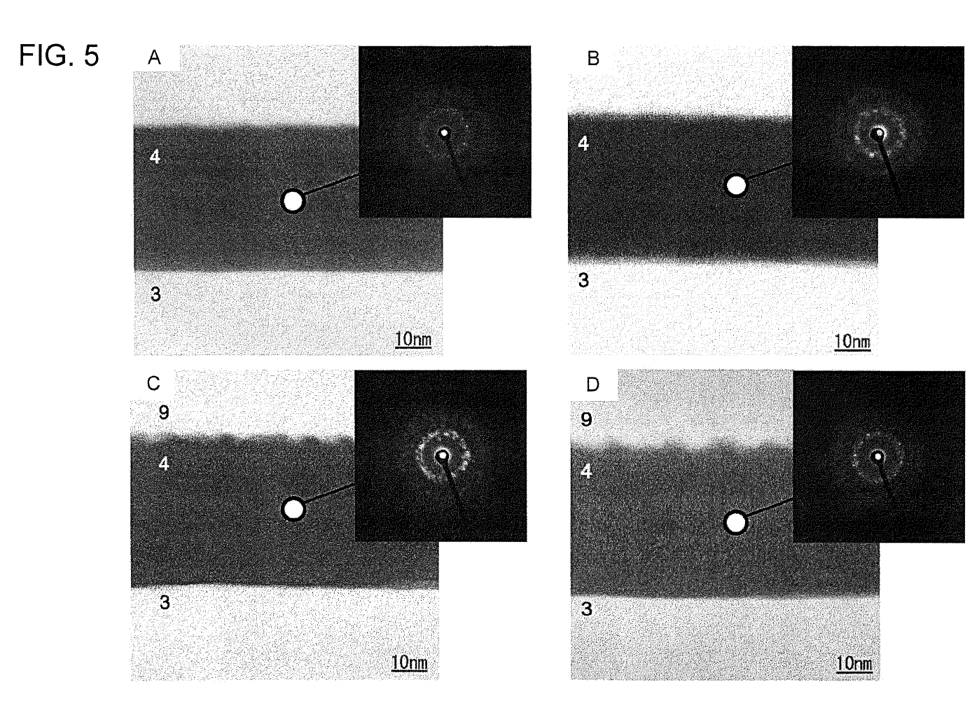

FIG. 5 illustrates the TEM observation results of a cross-section of the oxide semiconductor thin film at the following timings in the thin film transistor production process: A after the formation of the oxide semiconductor thin film, B after the pre-annealing, C after the formation of contact holes, and D after the post-annealing.

The electron diffraction patterns in bright circular regions in the oxide semiconductor thin film 4 in FIGS. 5A to 5D are illustrated on the right sides of FIGS. 5A to 5D. There are slightly brighter regions in the rings in all the states, which shows that the crystalline structure does not change so much through the thin film transistor production process.

Next, it will be demonstrated that the crystalline structure is not observed when the constituent elements of the thin film are changed.

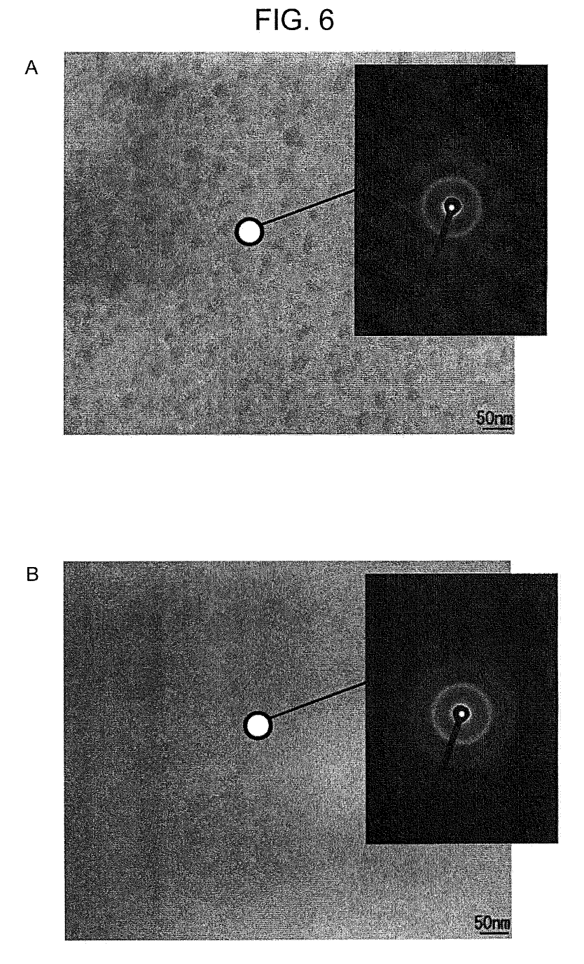

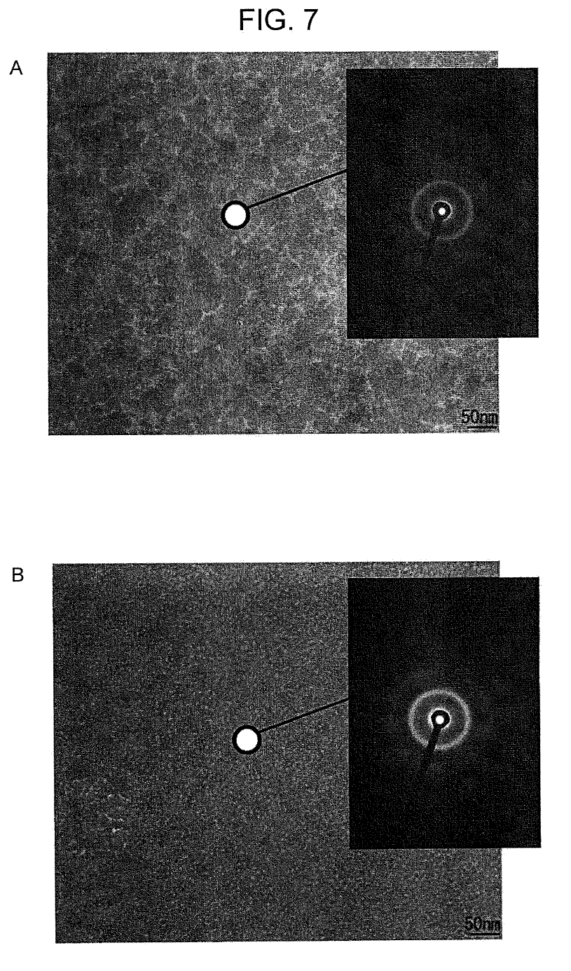

A thin film transistor including an oxide semiconductor thin film constituted by an In—Ga—Zn—O film whose constituent elements were different from those of the above oxide semiconductor thin film 4 was produced. FIGS. 6 and 7 illustrate the TEM observation results of a surface of the oxide semiconductor thin film formed and a surface of the oxide semiconductor thin film subjected to pre-annealing. The composition of the In—Ga—Zn—O film is as follows.

### In:Ga:Zn=33.3:33.3:33.3 at %

Specifically, the oxide semiconductor thin film was formed by a sputtering method under the following conditions using a sputtering target having the same composition as the In—Ga—Zn—O film.

Sputtering apparatus: “CS-200” manufactured by ULVAC, Inc.
Substrate temperature: room temperature
Gas pressure: 1 mTorr or 5 mTorr

### Carrier gas: Ar

Partial pressure of oxygen: 100×O₂/(Ar+O₂)=4 vol %
Film formation power density: 2.55 W/cm²
Sputtering target used: In:Ga:Zn=33.3:33.3:33.3 at %

FIG. 6 illustrates the result obtained when the In—Ga—Zn—O film was formed at a gas pressure of 1 mTorr. FIG. 6A illustrates the result after the formation of the In—Ga—Zn—O film and FIG. 6B illustrates the result after the pre-annealing. FIG. 7 illustrates the result obtained when the In—Ga—Zn—O film was formed at a gas pressure of 5 mTorr. FIG. 7A illustrates the result after the formation of the In—Ga—Zn—O film and FIG. 7B illustrates the result after the pre-annealing.

The electron diffraction patterns in bright circular regions in the oxide semiconductor thin films in FIGS. 6 and 7 are illustrated on the right sides of FIGS. 6 and 7. In FIG. 5, spots (diffraction spots) are observed in a white ring located on the outer side of the bright center. On the other hand, in FIGS. 6 and 7, such spots are hardly observed. In other words, microcrystals are contained in FIG. 5 whereas microcrystals are not contained in FIGS. 6 and 7. Therefore, it is clear from the drawings on the right sides of FIGS. 6 and 7 that there is no particular difference in emission intensity in the ring and thus an amorphous structure is formed.

### (X-Ray Diffraction Measurement)

In No. 1-1 in Table 1, an oxide semiconductor thin film 4 (In—Ga—Sn—O film, thickness: 40 nm) having the following composition was formed on a glass substrate (EAGLE 2000 manufactured by Corning, diameter 100 mm×thickness 0.7 mm) by sputtering.

### In:Ga:Sn=42.7:26.7:30.6 at %

Specifically, an oxide semiconductor thin film 4 was formed by a sputtering method under the following conditions using a sputtering target having the same composition as the above oxide semiconductor thin film 4.

Sputtering apparatus: “CS-200” manufactured by ULVAC, Inc.
Substrate temperature: room temperature
Gas pressure: 1 mTorr
Partial pressure of oxygen: 100×O₂/(Ar+O₂)=4 vol %
Film formation power density: 2.55 W/cm²
Sputtering target used: In:Ga:Sn=42.7:26.7:30.6 at %

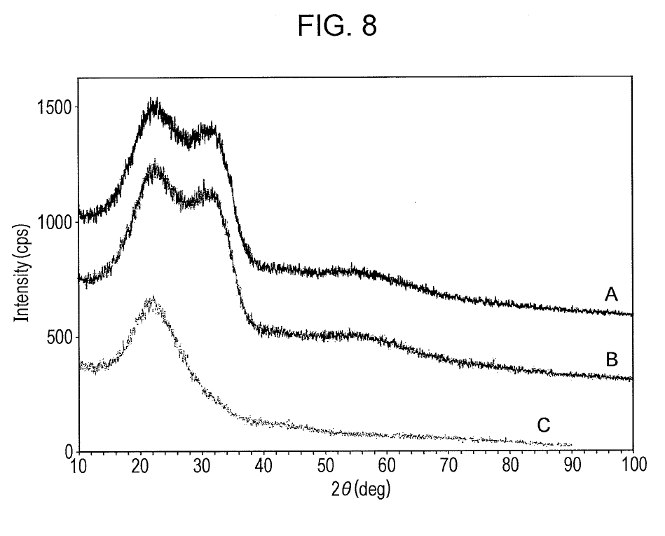

After the formation of the In—Ga—Sn—O film, X-ray diffraction measurement was performed. The X-ray diffraction measurement was performed with a Smart Lab manufactured by Rigaku Corporation using a Cu target at a target output of 45 kV-200 mA with a 2θ scan mode. The incident angle of X-rays was 0.5° and the measurement angle was 10° to 100°. FIG. 8A illustrates the result of the X-ray diffraction measurement after the formation of the In—Ga—Sn—O film.

After the In—Ga—Sn—O film was formed, pre-annealing was performed to improve the film quality. The pre-annealing was performed in an air atmosphere at 350° C. for 1 hour. After the pre-annealing, the X-ray diffraction measurement was performed under the same conditions as above. FIG. 8B illustrates the measurement result. FIG. 8C illustrates the result of the X-ray diffraction measurement of a glass substrate for reference.

In FIG. 8C in which the X-ray diffraction measurement was performed on the glass substrate, a broad halo pattern was observed at about 2θ=23°. In contrast, in FIG. 8A in which the X-ray diffraction measurement was performed after the formation of the In—Ga—Sn—O film and FIG. 8B in which the X-ray diffraction measurement was performed after the pre-annealing, halo patterns derived from the oxide semiconductor thin film were observed at about 31° and 55° in addition to the halo pattern derived from the glass substrate. However, sharp peaks indicating crystals were not observed.

Since the crystallite size that can be measured by the X-ray diffraction measurement is about 1 nm, the size of crystal grains formed is believed to be less than 1 nm. This shows that most of the film has an amorphous structure and the size of crystal grains formed is less than 1 nm.

As described above, a part of the In—Ga—Sn—O film is crystallized, but most of the In—Ga—Sn—O film has an amorphous structure. Therefore, the oxide semiconductor thin film according to the present invention is believed to have both ease of etching and high mobility due to extremely short range order formation.

### Example 2

In Example 2 according to the first TFT, four types of TFTs having the following patterns (i) to (iv) were produced, and the transistor characteristics were evaluated after the passivation film (insulating film) 6 was formed. In Example 2, only the passivation film contained SiNx.

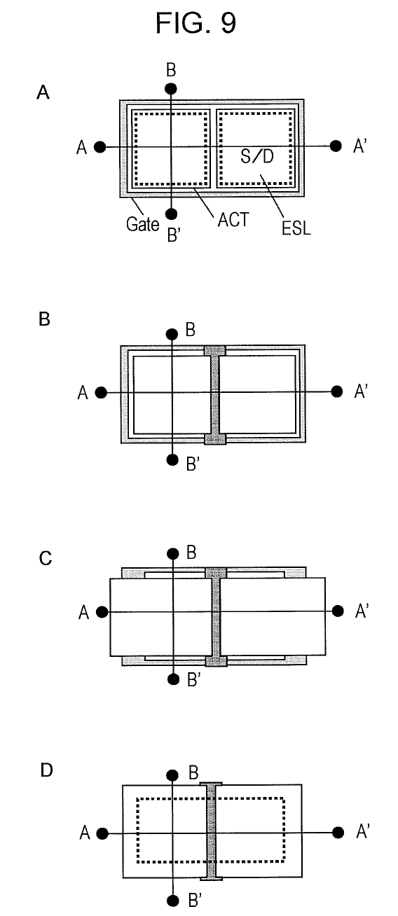

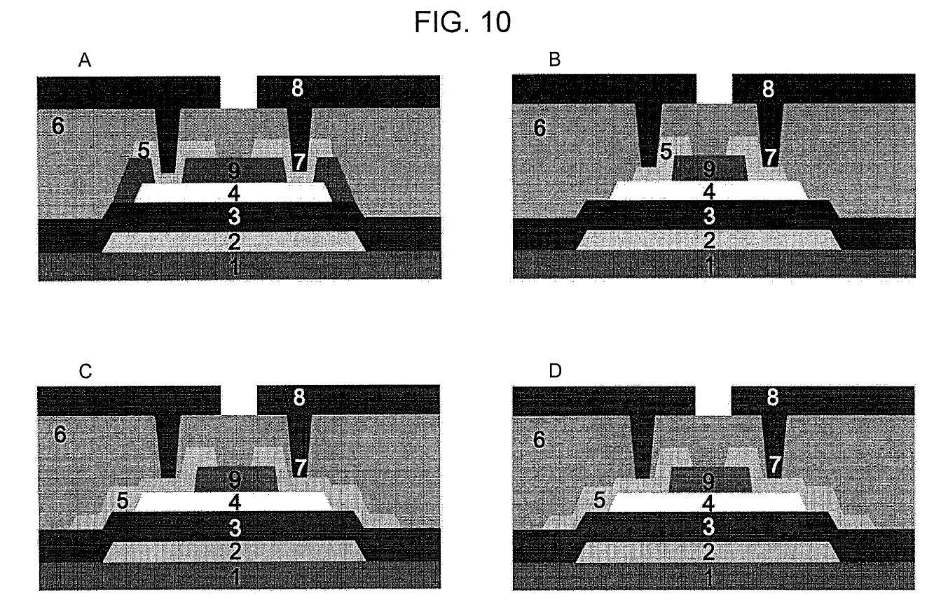

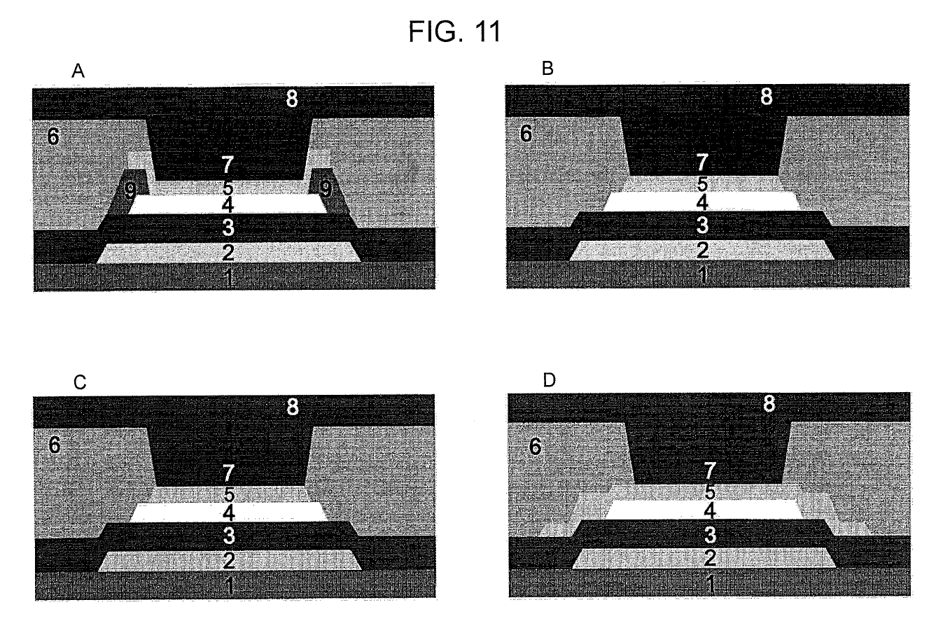

FIGS. 9A to 9D are plan views of the thin film transistors illustrated to clarify the shapes of the TFTs used in Example 2. FIGS. 10A to 10D are sectional views taken along line A-A′ in FIGS. 9A to 9D, respectively. FIGS. 11A to 11D are sectional views taken along line B-B′ in FIGS. 9A to 9D, respectively. In FIG. 9, ACT indicates a region corresponding to the oxide semiconductor thin film 4.

Pattern (i): Refer to FIG. 9A, FIG. 10A, and FIG. 11A

The pattern (i) corresponds to FIG. 1. The source/drain electrode 5 is not directly in contact with both ends of the oxide semiconductor thin film 4, and is directly in contact with a part of the upper surface of the oxide semiconductor thin film 4. Furthermore, the etch stop layer 9 is in contact with both ends of the oxide semiconductor thin film 4, and is directly in contact with a part of the upper surface of the oxide semiconductor thin film 4.

Pattern (ii): Refer to FIG. 9B, FIG. 10B, and FIG. 11B

The source/drain electrode 5 is not directly in contact with both ends of the oxide semiconductor thin film 4, and is directly in contact with a part of the upper surface of the oxide semiconductor thin film 4. Furthermore, the etch stop layer 9 is not in contact with both ends of the oxide semiconductor thin film 4, and is directly in contact with a part of the upper surface of the oxide semiconductor thin film 4.

Pattern (iii): Refer to FIG. 9C, FIG. 10C, and FIG. 11C

The source/drain electrode 5 is directly in contact with both ends of the oxide semiconductor thin film 4 in a channel length direction in the sectional view of FIG. 10C, but is not directly in contact with both the ends in the sectional view of FIG. 11C. The source/drain electrode 5 is directly in contact with a part of the upper surface of the oxide semiconductor thin film 4. Furthermore, the etch stop layer 9 is not in contact with both ends of the oxide semiconductor thin film 4, and is directly in contact with a part of the upper surface of the oxide semiconductor thin film 4.

Pattern (iv): Refer to FIG. 9D, FIG. 10D, and FIG. 11D

The pattern (iv) corresponds to FIG. 2. The source/drain electrode 5 is directly in contact with both ends of the oxide semiconductor thin film 4, and is directly in contact with a part of the upper surface of the oxide semiconductor thin film 4. Furthermore, the etch stop layer 9 is not in contact with both ends of the oxide semiconductor thin film 4, and is directly in contact with a part of the upper surface of the oxide semiconductor thin film 4.

The TFT having the pattern (iv) was produced by designing a mask that provides a desired shape. Hereafter, a method for producing the TFT having the pattern (i) will be described as an example. The pattern is the same as that in Example 1, and therefore points different from those in Example 1 will be mainly described.

As in Example 1, a gate electrode 2 and a gate insulating film 3 were sequentially formed on a glass substrate 1. Then, an oxide semiconductor thin film (In—Ga—Sn—O, thickness: 40 nm) having the same composition as in Example 1 was formed. The sputtering conditions were the same as those in Example 1 except for the following points.

Gas pressure: 1 mTorr
Partial pressure of oxygen: 100×O₂/(Ar+O₂)=4 vol %
Film formation power density: 2.55 W/cm²

For comparison, an In—Ga—Zn—O film (thickness: 40 nm) described in PTL 1 and the like was formed as an oxide semiconductor thin film. The composition of the In—Ga—Zn—O film is as follows.

### In:Ga:Zn=33.3:33.3:33.3 at %

Subsequently, an etch stop layer 9, a source/drain electrode 5, a passivation film 6, and contact holes 7 were formed in the same manner as in Example 1. Then, the following heat treatment was performed as post-annealing as shown in Table 2. For reference, TFTs without the heat treatment were also produced.

### Nitrogen Atmosphere at 250° C., 260° C., and 270° C. for 30 Minutes

Finally, ITO films (thickness: 80 nm) were formed as transparent conductive films 8 in the same manner as in Example 1 to produce a thin film transistor having the pattern (i).

The S value, the threshold voltage Vth, and the field effect mobility μFE were measured for each of the produced thin film transistors in the same manner as in Example 1.

Table 2 shows the results.

TABLE 2

| | | | Sputtering conditions | | | | | | |
|---|---|---|---|---|---|---|---|---|---|
| | | | | | Film | | Thin film transistor | | |
| | Composition | | Partial | | formation | Post-annealing | characteristics | | |
| | of oxide | | pressure | Gas | power | conditions | | Threshold | |
| | semiconductor | Pattern | of oxygen | pressure | density | Temperature, | Mobility | voltage | S value |
| No. | thin film | of TFT | (vol %) | (mTorr) | (W/cm²) | Time | (cm²/Vs) | (V) | (V/decade) |
| 2-1 | In—Ga—Sn—O | (i) | 4 | 1 | 2.55 | — | 8.11 | −5.5 | 1.07 |
| 2-2 | In—Ga—Sn—O | (ii) | 4 | 1 | 2.55 | — | 8.91 | −6.75 | 1.05 |
| 2-3 | In—Ga—Sn—O | (iii) | 4 | 1 | 2.55 | — | 8.1 | −3.5 | 0.76 |
| 2-4 | In—Ga—Sn—O | (iv) | 4 | 1 | 2.55 | — | 7.16 | 1.5 | 0.56 |
| 2-5 | In—Ga—Sn—O | (i) | 4 | 1 | 2.55 | 250° C., 30 minutes | 41.2 | 3.3 | 0.2 |
| 2-6 | In—Ga—Sn—O | (ii) | 4 | 1 | 2.55 | 250° C., 30 minutes | — | — | — |
| 2-7 | In—Ga—Sn—O | (iii) | 4 | 1 | 2.55 | 250° C., 30 minutes | — | — | — |
| 2-8 | In—Ga—Sn—O | (iv) | 4 | 1 | 2.55 | 250° C., 30 minutes | 13.4 | 3.5 | 0.2 |
| 2-9 | In—Ga—Sn—O | (ii) | 4 | 1 | 2.55 | 260° C., 30 minutes | — | — | — |
| 2-10 | In—Ga—Sn—O | (iii) | 4 | 1 | 2.55 | 260° C., 30 minutes | — | — | — |
| 2-11 | In—Ga—Sn—O | (iv) | 4 | 1 | 2.55 | 260° C., 30 minutes | 15.0 | 3.0 | 0.3 |
| 2-12 | In—Ga—Sn—O | (i) | 4 | 1 | 2.55 | 270° C., 30 minutes | 66.8 | 3.0 | 0.2 |
| 2-13 | In—Ga—Sn—O | (ii) | 4 | 1 | 2.55 | 270° C., 30 minutes | — | — | — |
| 2-14 | In—Ga—Sn—O | (iii) | 4 | 1 | 2.55 | 270° C., 30 minutes | — | — | — |
| 2-15 | In—Ga—Sn—O | (iv) | 4 | 1 | 2.55 | 270° C., 30 minutes | 16.3 | 3.3 | 0.2 |
| 2-16 | In—Ga—Zn—O | (i) | 4 | 1 | 2.55 | — | 5.7 | 9.3 | 0.7 |
| 2-17 | In—Ga—Zn—O | (ii) | 4 | 1 | 2.55 | — | 4.9 | −1.5 | 0.9 |
| 2-18 | In—Ga—Zn—O | (iii) | 4 | 1 | 2.55 | — | 5.4 | −1.0 | 1.4 |
| 2-19 | In—Ga—Zn—O | (iv) | 4 | 1 | 2.55 | — | 5.0 | 11.3 | 0.8 |
| 2-20 | In—Ga—Zn—O | (i) | 4 | 1 | 2.55 | 250° C., 30 minutes | 6.2 | 10.0 | 0.5 |
| 2-21 | In—Ga—Zn—O | (ii) | 4 | 1 | 2.55 | 250° C., 30 minutes | 6.3 | 7.0 | 0.5 |
| 2-22 | In—Ga—Zn—O | (iii) | 4 | 1 | 2.55 | 250° C., 30 minutes | 6.6 | 6.5 | 0.4 |
| 2-23 | In—Ga—Zn—O | (iv) | 4 | 1 | 2.55 | 250° C., 30 minutes | 6.1 | 8.3 | 0.5 |
| 2-24 | In—Ga—Zn—O | (i) | 4 | 1 | 2.55 | 260° C., 30 minutes | 7.0 | 9.0 | 0.5 |
| 2-25 | In—Ga—Zn—O | (ii) | 4 | 1 | 2.55 | 260° C., 30 minutes | 6.8 | 7.2 | 0.5 |
| 2-26 | In—Ga—Zn—O | (iii) | 4 | 1 | 2.55 | 260° C., 30 minutes | 6.8 | 6.2 | 0.4 |
| 2-27 | In—Ga—Zn—O | (iv) | 4 | 1 | 2.55 | 260° C., 30 minutes | 6.5 | 8.0 | 0.6 |
| 2-28 | In—Ga—Zn—O | (i) | 4 | 1 | 2.55 | 270° C., 30 minutes | 7.0 | 7.7 | 0.6 |
| 2-29 | In—Ga—Zn—O | (ii) | 4 | 1 | 2.55 | 270° C., 30 minutes | 7.1 | 7.0 | 0.5 |
| 2-30 | In—Ga—Zn—O | (iii) | 4 | 1 | 2.55 | 270° C., 30 minutes | 6.9 | 7.5 | 0.5 |
| 2-31 | In—Ga—Zn—O | (iv) | 4 | 1 | 2.55 | 270° C., 30 minutes | 6.7 | 7.8 | 0.5 |

Nos. 2-1 to 2-15 are examples in which an In—Ga—Sn oxide having the composition specified in the present invention is used as the oxide semiconductor thin film 4. In Nos. 2-5 and 2-12 of Invention Examples having the pattern (i) and produced under the production conditions specified in the present invention, a very high mobility of 40 cm²/Vs or more was achieved. In particular, in No. 2-12 in which the post-annealing temperature after the formation of the passivation film is 270° C., the mobility was as very high as about 67 cm²/Vs.

In contrast, in Nos. 2-6, 2-9, and 2-13 of Comparative Examples having the pattern (ii) and Nos. 2-7, 2-10, and 2-14 of Comparative Examples having the pattern (iii), the TFTs were made conductive. Therefore, various characteristics were not measured (“-” in Table 2).

In Nos. 2-8, 2-11, and 2-15 of Comparative Examples having the pattern (iv), which is not the pattern specified in the present invention, a desired high mobility was not achieved.

The reason why a very high mobility is achieved by the configuration of the pattern (i) according to the present invention is unclear, but is assumed to be as follows. In the pattern (i), as described above, the upper surface of the oxide semiconductor thin film 4 is in contact with the source/drain electrode 5 through the contact holes 7 in the etch stop layer 9. That is, both ends of the oxide semiconductor thin film 4 are not directly in contact with the source/drain electrode 5. Furthermore, the etch stop layer 9 is disposed on the oxide semiconductor thin film 4 in a portion other than the contact holes 7. Herein, Mo and Al, which are materials for the source/drain electrode 5, hardly causes hydrogen permeation. Therefore, hydrogen is supplied from SiNx of the passivation film 6 formed on the source/drain electrode 5 through the etch stop layer 9 (e.g., SiOx) on a channel, or is directly supplied from the etch stop layer 9. In Example 2, the amount of hydrogen in the etch stop layer 9 (SiOx) is about 5.0 at %, and the amount of hydrogen in the passivation film 6 (SiNx) is about 32 at %. Thus, hydrogen in the passivation film 6 is highly likely to diffuse into the oxide semiconductor thin film 4 and contribute to achieving high mobility. It is believed that hydrogen passivates a tail level below conduction band, which reduces defects in the oxide semiconductor thin film 4 and achieves high mobility.

In contrast, when both ends of the oxide semiconductor thin film 4 in the channel width direction are directly in contact with the passivation film 6 as in the cases of the pattern (ii) and the pattern (iii), hydrogen is excessively supplied to the oxide semiconductor thin film 4. Thus, it is believed that there is an excessive amount of carriers and the TFT is made conductive.

When a region of the oxide semiconductor thin film 4 other than the channel region is covered with the source/drain electrode 5 as in the case of the pattern (iv), it is believed that the supply of hydrogen is limited and thus high mobility is not achieved.

In Nos. 2-16 to 2-31 in which an In—Ga—Zn oxide having a known composition is used as the oxide semiconductor thin film 4, a considerably improved mobility was not measured, and the mobility was at most 7.1 cm²/Vs. That is, an improvement in the mobility achieved as a result of post-annealing and an improvement in the mobility achieved by controlling the shape of a TFT were not observed unlike the In—Ga—Sn oxide having the composition according to the present invention.

### Example 3

In Example 3 according to the second TFT, a TFT having the pattern (i) was produced and the transistor characteristics were evaluated in the same manner as in Example 1, except that the configuration of the etch stop layer was different from that in Example 1. In Tables 3 to 5, the production method described below is referred to as a production method A, and TFTs of Nos. 3-1 to 3-8 were produced by the production method A. In Example 3, a passivation film 6 for protecting an oxide semiconductor transistor is not disposed in order to emphasize the advantage obtained when an SiNx-containing layer is used as the etch stop layer 9. However, the passivation film 6 may be disposed as in Examples 1 and 2.

First, a Mo thin film with a thickness of 100 nm serving as a gate electrode 2 and a SiO₂ (thickness: 200 nm) serving as a gate insulating film 3 were sequentially formed on a glass substrate 1 (EAGLE 2000 manufactured by Corning, diameter 100 mm×thickness 0.7 mm). The gate electrode 2 was formed by a DC sputtering method using a pure Mo sputtering target under the conditions of film formation temperature: room temperature, film formation power density: 3.8 W/cm², carrier gas: Ar, gas pressure during film formation: 2 mTorr, and Ar gas flow rate: 20 sccm. The gate insulating film 3 was formed by a plasma CVD method under the conditions of carrier gas: mixture gas of SiH₄ and N₂O, film formation power density: 0.96 W/cm², film formation temperature: 320° C., and gas pressure during film formation: 133 Pa.

Subsequently, an oxide semiconductor thin film 4 (In—Ga—Sn—O film, thickness: 40 nm) having the following composition was formed under various sputtering conditions shown in Table 3.

### In:Ga:Sn=42.7:26.7:30.6 at %

Specifically, an oxide semiconductor thin film was formed by a sputtering method under the following conditions using a sputtering target having the same composition as the above oxide semiconductor thin film 4.

Sputtering apparatus: “CS-200” manufactured by ULVAC, Inc.
Substrate temperature: room temperature
Gas pressure: 1 mTorr

### Carrier gas: Ar

Partial pressure of oxygen: 100×O₂/(Ar+O₂)=4 vol %
Film formation power density: 2.55 W/cm²
Sputtering target used: In:Ga:Sn=42.7:26.7:30.6 at %

The contents of the metal elements in the oxide semiconductor thin film were analyzed using samples separately prepared by forming an oxide semiconductor thin film with a thickness of 40 nm on a glass substrate by a sputtering method in the same manner as above. The analysis was conducted by ICP (inductively coupled plasma) emission spectroscopy using a CIROS Mark II (manufactured by Rigaku Corporation).

After the oxide semiconductor thin film 4 was formed as described above, patterning was performed by photolithography and wet etching. The wet etchant was “ITO-07N” manufactured by KANTO CHEMICAL CO., INC. In Example 3, it was confirmed that there was no residue generated as a result of the wet etching and thus the etching was appropriately performed in all the oxide semiconductor thin films used in the experiment.

As described above, after the oxide semiconductor thin film 4 was patterned, pre-annealing was performed to improve the film quality. The pre-annealing was performed in an air atmosphere at 350° C. for 1 hour.

After the pre-annealing, an SiOx film 9-1 and an SiNx film 9-2 were formed as an etch stop layer 9 on the oxide semiconductor thin film as illustrated in Table 3, FIG. 12, and FIG. 13 (FIG. 13A). The SiOx film 9-1 was formed by a plasma CVD method using a mixture gas of N₂O and SiH₄ under the conditions of film formation power density: 0.32 W/cm², film formation temperature: 230° C., and gas pressure during film formation: 133 Pa. The SiNx film 9-2 was formed by a plasma CVD method using a mixture gas of SiH₄, N₂, and NH₃ under the conditions of film formation power density: 0.32 W/cm², film formation temperature: 150° C., and gas pressure during film formation: 133 Pa. After the formation of the SiOx film 9-1 and the SiNx film 9-2, the etch stop layer 9 was patterned by photolithography and dry etching (FIG. 13B). In Example 3-8, only an SiOx film was formed on the oxide semiconductor thin film for comparison.

Subsequently, a pure Mo film with a thickness of 200 nm was formed above the oxide semiconductor thin film 4 by a sputtering method to form a source/drain electrode 5. The pure Mo film was formed under the conditions of input power: DC 300 W (film formation power density: 3.8 W/cm²), carrier gas: Ar, gas pressure: 2 mTorr, and substrate temperature: room temperature.

Subsequently, the source/drain electrode 5 was patterned by photolithography and wet etching to form contact holes 7 used for probing for evaluating transistor characteristics (FIG. 13C). Specifically, a mixed acid etchant made of a mixture solution containing phosphoric acid:nitric acid:acetic acid=70:2:10 (mass ratio) at 40° C. was used.

After the source/drain electrode 5 was formed, heat treatment was performed as post-annealing in a nitrogen atmosphere at 260° C. for 30 minutes.

FIG. 12 is a sectional view illustrating the produced transistor, and FIG. 13 includes sectional views illustrating the production process of the transistor.

The produced thin film transistors (Nos. 3-2, 3-3, 3-7, and 3-8) had a channel length of 20 μm and a channel width of 200 μm. The produced thin film transistor (No. 3-4) had a channel length of 10 μm and a channel width of 200 μm. The produced thin film transistor (No. 3-5) had a channel length of 10 μm and a channel width of 100 μm. The produced thin film transistor (No. 3-6) had a channel length of 10 μm and a channel width of 50 μm.

The above-described various characteristics (S value, threshold voltage Vth, and field effect mobility μFE) were investigated for the TFTs in the same manner as in Examples 1 and 2.

Table 3 shows the results. For reference, the configuration, physical properties, and various characteristics of a TFT produced by the method in Example 1 are shown as No. 3-1.

TABLE 3

| | | Sputtering conditions | | | | | | | | | | |
|---|---|---|---|---|---|---|---|---|---|---|---|---|
| | | | | Film | Thin film | | | Passivation | Thin film transistor | | | |
| | | Partial | | formation | properties | Etch stop layer | | film | characteristics | | | |
| | | pressure | Gas | power | Electrical | Structure | Pro- | Structure | | | Threshold | |
| | Pattern | of oxygen | pressure | density | resistivity | (upper layer/ | duction | (upper layer/ | W/L | Mobility | voltage | S value |
| No. | of TFT | (vol %) | (mTorr) | (W/cm²) | (Ωcm) | lower layer) | method | lower layer) | (μm) | (cm²/Vs) | (V) | (V/decade) |
| 3-1 | (i) | 4 | 1 | 2.55 | 1.05E+01 | SiOx: 100 nm | A | SiNx/SiOx = | 200/20 | 66.2 | 0 to 2 | ≦0.4 |
| | | | | | | | | 150 nm/ | | | | |
| | | | | | | | | 100 nm | | | | |
| 3-2 | (i) | 4 | 1 | 2.55 | 1.05E+01 | SiNx/SiOx = | A | — | 200/20 | 50.1 | 0 to 2 | ≦0.4 |
| | | | | | | 150 nm/200 nm | | | | | | |
| 3-3 | (i) | 4 | 1 | 2.55 | 1.05E+01 | SiNx/SiOx = | A | — | 200/20 | 66.3 | 0 to 2 | ≦0.4 |
| | | | | | | 150 nm/100 nm | | | | | | |
| 3-4 | (i) | 4 | 1 | 2.55 | 1.05E+01 | SiNx/SiOx = | A | — | 200/10 | 40.2 | 0 to 2 | ≦0.4 |
| | | | | | | 150 nm/100 nm | | | | | | |
| 3-5 | (i) | 4 | 1 | 2.55 | 1.05E+01 | SiNx/SiOx = | A | — | 100/10 | 57.6 | 0 to 2 | ≦0.4 |
| | | | | | | 150 nm/100 nm | | | | | | |
| 3-6 | (i) | 4 | 1 | 2.55 | 1.05E+01 | SiNx/SiOx = | A | — | 50/10 | 81.5 | 0 to 2 | ≦0.4 |
| | | | | | | 150 nm/100 nm | | | | | | |
| 3-7 | (i) | 4 | 1 | 2.55 | 1.05E+01 | SiNx/SiOx = | A | — | 200/20 | 62.3 | 0 to 2 | ≦0.4 |
| | | | | | | 100 nm/100 nm | | | | | | |
| 3-8 | (i) | 4 | 1 | 2.55 | 1.05E+01 | SiOx: 200 nm | A | — | 200/20 | 7.1 | 0 to 2 | ≦0.4 |

As is clear from Table 3, when the etch stop layer was formed of only an SiOx film (No. 3-8), the mobility was substantially equal to that of a typical In—Ga—Zn—O (IGZO) film. In contrast, when the etch stop layer had a multilayer structure including an SiOx film and an SiNx film (Nos. 3-2 to 3-7), high mobility was achieved. That is, when an SiNx film was formed as an upper layer, high mobility was achieved. The mobility increased as the ratio of the thickness of the SiNx film to the total thickness of the etch stop layer increased. Furthermore, the mobility increased as the channel length increased, and the mobility increased as the channel width decreased.

### Example 4

In Nos. 4-2 and 4-3, a second TFT including an etch stop layer whose structure was different from that in Example 1 was produced by a production method below (hereafter referred to as a production method B), which is different from that in Example 3. The transistor characteristics were evaluated.

In Example 4, a passivation film 6 for protecting an oxide semiconductor transistor is not disposed for the sake of convenience in order to emphasize the advantage obtained when an SiNx-containing layer is used as the etch stop layer 9. However, the passivation film 6 may be disposed as in Examples 1 and 2.

First, a Mo thin film with a thickness of 100 nm serving as a gate electrode 2 and a SiO₂ (thickness: 200 nm) serving as a gate insulating film 3 were sequentially formed on a glass substrate 1 (EAGLE 2000 manufactured by Corning, diameter 100 mm×thickness 0.7 mm). The gate electrode 2 was formed by a DC sputtering method using a pure Mo sputtering target under the conditions of film formation temperature: room temperature, film formation power density: 3.8 W/cm², carrier gas: Ar, gas pressure during film formation: 2 mTorr, and Ar gas flow rate: 20 sccm. The gate insulating film 3 was formed by a plasma CVD method under the conditions of carrier gas: mixture gas of SiH₄ and N₂O, film formation power density: 0.96 W/cm², film formation temperature: 320° C., and gas pressure during film formation: 133 Pa.

Subsequently, an oxide semiconductor thin film 4 (In—Ga—Sn—O film, thickness: 40 nm) having the following composition was formed under various conditions shown in Table 4.

### In:Ga:Sn=42.7:26.7:30.6 at %

Specifically, an oxide semiconductor thin film was formed by a sputtering method under the following conditions using a sputtering target having the same composition as the above oxide semiconductor thin film 4.

Sputtering apparatus: “CS-200” manufactured by ULVAC, Inc.
Substrate temperature: room temperature
Gas pressure: 1 mTorr

### Carrier gas: Ar

Partial pressure of oxygen: 100×O₂/(Ar+O₂)=4 vol %
Film formation power density: 2.55 W/cm²
Sputtering target used: In:Ga:Sn=42.7:26.7:30.6 at %

The contents of the metal elements in the oxide semiconductor thin film were analyzed using samples separately prepared by forming an oxide semiconductor thin film with a thickness of 40 nm on a glass substrate by a sputtering method in the same manner as above. The analysis was conducted by ICP (inductively coupled plasma) emission spectroscopy using a CIROS Mark II (manufactured by Rigaku Corporation).

After the oxide semiconductor thin film 4 was formed as described above, patterning was performed by photolithography and wet etching. The wet etchant was “ITO-07N” manufactured by KANTO CHEMICAL CO., INC. In Example 4, it was confirmed that there was no residue generated as a result of the wet etching and thus the etching was appropriately performed in all the oxide semiconductor thin films used in the experiment.

As described above, after the oxide semiconductor thin film 4 was patterned, pre-annealing was performed to improve the film quality. The pre-annealing was performed in an air atmosphere at 350° C. for 1 hour.

After the pre-annealing, an SiOx film 9-1 and an SiNx film 9-2 were formed as an etch stop layer 9 on the oxide semiconductor thin film as illustrated in Table 4, FIG. 12, and FIG. 13 (FIG. 13A). The SiOx film 9-1 was formed by a plasma CVD method using a mixture gas of N₂O and SiH₄ under the conditions of film formation power density: 0.32 W/cm², film formation temperature: 230° C., and gas pressure during film formation: 133 Pa. The SiNx film 9-2 was formed by a plasma CVD method using a mixture gas of SiH₄, N₂, and NH₃ under the conditions of film formation power density: 0.32 W/cm², film formation temperature: 150° C., and gas pressure during film formation: 133 Pa. Then, heat treatment was performed at post-annealing in a nitrogen atmosphere at 260° C. for 30 minutes. After the formation of the SiOx film 9-1 and the SiNx film 9-2, post-annealing was performed and then the etch stop layer 9 (9-1 and 9-2) was patterned by photolithography and dry etching (FIG. 13B).

Subsequently, a pure Mo film with a thickness of 200 nm was formed above the oxide semiconductor thin film 4 by a sputtering method to form a source/drain electrode 5. The pure Mo film was formed under the conditions of input power: DC 300 W (film formation power density: 3.8 W/cm²), carrier gas: Ar, gas pressure: 2 mTorr, and substrate temperature: room temperature.

Subsequently, the source/drain electrode 5 was patterned by photolithography and wet etching to form contact holes 7 used for probing for evaluating transistor characteristics (FIG. 13C). Specifically, a mixed acid etchant made of a mixture solution containing phosphoric acid:nitric acid:acetic acid=70:2:10 (mass ratio) at 40° C. was used.

FIG. 12 is a sectional view illustrating the produced transistor, and FIG. 13 includes sectional views illustrating the production process of the transistor.

The produced thin film transistor (No. 4-2) had a channel length of 20 μm and a channel width of 200 μm. The produced thin film transistor (No. 4-3) had a channel length of 10 μm and a channel width of 50 μm.

The above-described various characteristics (S value, threshold voltage Vth, and field effect mobility μFE) were investigated for the TFTs in the same manner as in Examples 1 to 3.

Table 4 shows the results. For reference, the configuration, physical properties, and various characteristics of a TFT produced by the method in Example 1 are shown as No. 4-1.

TABLE 4

| | | Sputtering conditions | | | | | | | | | | |
|---|---|---|---|---|---|---|---|---|---|---|---|---|
| | | | | Film | Thin film | | | Passivation | Thin film transistor | | | |
| | | Partial | | formation | properties | Etch stop layer | | film | characteristics | | | |
| | | pressure | Gas | power | Electrical | Structure | Pro- | Structure | | | Threshold | |
| | Pattern | of oxygen | pressure | density | resistivity | (upper layer/ | duction | (upper layer/ | W/L | Mobility | voltage | S value |
| No. | of TFT | (vol %) | (mTorr) | (W/cm²) | (Ωcm) | lower layer) | method | lower layer) | (μm) | (cm²/Vs) | (V) | (V/decade) |
| 4-1 | (i) | 4 | 1 | 2.55 | 1.05E+01 | SiOx: 100 nm | A | SiNx/SiOx = | 200/20 | 66.2 | 0 to 2 | ≦0.4 |
| | | | | | | | | 150 nm/ | | | | |
| | | | | | | | | 100 nm | | | | |
| 4-2 | (i) | 4 | 1 | 2.55 | 1.05E+01 | SiNx/SiOx = | B | — | 200/20 | 70.1 | 0 to 2 | ≦0.4 |
| | | | | | | 150 nm/100 nm | | | | | | |
| 4-3 | (i) | 4 | 1 | 2.55 | 1.05E+01 | SiNx/SiOx = | B | — | 50/10 | 45.3 | 0 to 2 | ≦0.4 |
| | | | | | | 150 nm/100 nm | | | | | | |

As is clear from Table 4, when the etch stop layer was formed of only an SiOx film, the mobility was substantially equal to that of a typical In—Ga—Zn—O (IGZO) film. In contrast, when the etch stop layer had a multilayer structure including an SiOx film and an SiNx film, the SiNx film was formed as an upper layer and thus high mobility was achieved. It was also found from Tables 3 and 4 that after the etch stop layer 9 is formed, the post-annealing may be performed before the formation of the source/drain electrode 5 or after the formation of the source/drain electrode 5.

### Example 5

In Example 5, a TFT was produced in substantially the same manner as in Example 3, except that the pattern (iv) was employed instead of the pattern (i), and the transistor characteristics were evaluated.

First, a Mo thin film with a thickness of 100 nm serving as a gate electrode 2 and a SiO₂ (thickness: 200 nm) serving as a gate insulating film 3 were sequentially formed on a glass substrate 1 (EAGLE 2000 manufactured by Corning, diameter 100 mm×thickness 0.7 mm). The gate electrode 2 was formed by a DC sputtering method using a pure Mo sputtering target under the conditions of film formation temperature: room temperature, film formation power density: 3.8 W/cm², carrier gas: Ar, gas pressure during film formation: 2 mTorr, and Ar gas flow rate: 20 sccm. The gate insulating film 3 was formed by a plasma CVD method under the conditions of carrier gas: mixture gas of SiH₄ and N₂O, film formation power density: 1.27 W/cm², film formation temperature: 320° C., and gas pressure during film formation: 133 Pa.

Subsequently, an oxide semiconductor thin film 4 (In—Ga—Sn—O film, thickness: 40 nm) having the following composition was formed under conditions shown in Table 5.

### In:Ga:Sn=42.7:26.7:30.6 at %

Specifically, an oxide semiconductor thin film was formed by a sputtering method under the following conditions using a sputtering target having the same composition as the above oxide semiconductor thin film 4.

Sputtering apparatus: “CS-200” manufactured by ULVAC, Inc.
Substrate temperature: room temperature
Gas pressure: 1 mTorr

### Carrier gas: Ar

Partial pressure of oxygen: 100×O₂/(Ar+O₂)=4 vol %
Film formation power density: 2.55 W/cm²
Sputtering target used: In:Ga:Sn=42.7:26.7:30.6 at %

The contents of the metal elements in the oxide semiconductor thin film were analyzed using samples separately prepared by forming an oxide semiconductor thin film with a thickness of 40 nm on a glass substrate by a sputtering method in the same manner as above. The analysis was conducted by ICP (inductively coupled plasma) emission spectroscopy using a CIROS Mark II (manufactured by Rigaku Corporation).

After the oxide semiconductor thin film 4 was formed as described above, patterning was performed by photolithography and wet etching. The wet etchant was “ITO-07N” manufactured by KANTO CHEMICAL CO., INC. In Example 5, it was confirmed that there was no residue generated as a result of the wet etching and thus the etching was appropriately performed in all the oxide semiconductor thin films used in the experiment.

As described above, after the oxide semiconductor thin film 4 was patterned, pre-annealing was performed to improve the film quality. The pre-annealing was performed in an air atmosphere at 350° C. for 1 hour.

After the pre-annealing, an SiOx film 9-1 and an SiNx film 9-2 were formed as an etch stop layer 9 on the oxide semiconductor thin film as illustrated in Table 5, FIG. 14, and FIG. 15 (FIG. 15A). The SiOx film 9-1 was formed by a plasma CVD method using a mixture gas of N₂O and SiH₄ under the conditions of film formation power density: 0.32 W/cm², film formation temperature: 230° C., and gas pressure during film formation: 133 Pa. The SiNx film 9-2 was formed by a plasma CVD method using a mixture gas of SiH₄, N₂, and NH₃ under the conditions of film formation power density: 0.32 W/cm², film formation temperature: 150° C., and gas pressure during film formation: 133 Pa. After the formation of the SiOx film 9-1 and the SiNx film 9-2, the etch stop layer 9 was patterned by photolithography and dry etching (FIG. 15B).

Subsequently, a pure Mo film with a thickness of 200 nm was formed above the oxide semiconductor thin film 4 by a sputtering method to form a source/drain electrode 5. The pure Mo film was formed under the conditions of input power: DC 300 W (film formation power density: 3.8 W/cm²), carrier gas: Ar, gas pressure: 2 mTorr, and substrate temperature: room temperature.

Subsequently, the source/drain electrode 5 was patterned by photolithography and wet etching to form contact holes 7 used for probing for evaluating transistor characteristics (FIG. 15C). Specifically, a mixed acid etchant made of a mixture solution containing phosphoric acid:nitric acid:acetic acid=70:2:10 (mass ratio) at 40° C. was used.

After the source/drain electrode 5 was formed, heat treatment was performed as post-annealing in a nitrogen atmosphere at 260° C. for 30 minutes.

FIG. 14 is a sectional view illustrating the produced transistor, and FIG. 15 includes sectional views illustrating the production process of the transistor.

The produced thin film transistors (Nos. 5-1 to 5-3) had a channel length of 10 μm and channel widths of 200 μm, 100 μm, and 25 μm, respectively. The produced thin film transistors (Nos. 5-4 to 5-6) had a channel length of 25 μm and channel widths of 200 μm, 100 μm, and 25 μm, respectively.

The above-described various TFT characteristics (S value, threshold voltage Vth, and field effect mobility μFE) were investigated for the TFTs in the same manner as in Examples 1 to 4.

Table 5 shows the results.

TABLE 5

| | | Sputtering conditions | | | | | | | | | | |
|---|---|---|---|---|---|---|---|---|---|---|---|---|
| | | | | Film | Thin film | | | Passivation | Thin film transistor | | | |
| | | Partial | | formation | properties | Etch stop layer | | film | characteristics | | | |
| | | pressure | Gas | power | Electrical | Structure | Pro- | Structure | | | Threshold | |
| | Pattern | of oxygen | pressure | density | resistivity | (upper layer/ | duction | (upper layer/ | W/L | Mobility | voltage | S value |
| No. | of TFT | (vol %) | (mTorr) | (W/cm²) | (Ωcm) | lower layer) | method | lower layer) | (μm) | (cm²/Vs) | (V) | (V/decade) |
| 5-1 | (iv) | 4 | 1 | 2.55 | 1.05E+01 | SiNx/SiOx = | A | — | 200/10 | 42.3 | 0 to 2 | ≦0.4 |
| | | | | | | 150 nm/100 nm | | | | | | |
| 5-2 | (iv) | 4 | 1 | 2.55 | 1.05E+01 | SiNx/SiOx = | A | — | 100/10 | 43.3 | 0 to 2 | ≦0.4 |
| | | | | | | 150 nm/100 nm | | | | | | |
| 5-3 | (iv) | 4 | 1 | 2.55 | 1.05E+01 | SiNx/SiOx = | A | — | 25/10 | 46.8 | 0 to 2 | ≦0.4 |
| | | | | | | 150 nm/100 nm | | | | | | |
| 5-4 | (iv) | 4 | 1 | 2.55 | 1.05E+01 | SiNx/SiOx = | A | — | 200/25 | 80.1 | 0 to 2 | ≦0.4 |
| | | | | | | 150 nm/100 nm | | | | | | |
| 5-5 | (iv) | 4 | 1 | 2.55 | 1.05E+01 | SiNx/SiOx = | A | — | 100/25 | 87.1 | 0 to 2 | ≦0.4 |
| | | | | | | 150 nm/100 nm | | | | | | |
| 5-6 | (iv) | 4 | 1 | 2.55 | 1.05E+01 | SiNx/SiOx = | A | — | 25/25 | 99.9 | 0 to 2 | ≦0.4 |
| | | | | | | 150 nm/100 nm | | | | | | |

As described above, the mobility was low when the etch stop layer was formed of only an SiOx film. However, as is clear from Table 5, when the etch stop layer had a multilayer structure including an SiOx film and an SiNx film and the etch stop layer was disposed only in a channel region of the oxide semiconductor thin film, a high mobility of about 40 cm²/Vs or more was achieved. It was also found that when the etch stop layer had a multilayer structure including an SiOx film and an SiNx film and the etch stop layer was disposed only in a channel region of the oxide semiconductor thin film, the mobility was high regardless of the channel width.

### REFERENCE SIGNS LIST

1 substrate
2 gate electrode
3 gate insulating film
4 oxide semiconductor thin film
5 source/drain electrode
6 passivation film
7 contact hole
8 transparent conductive film
9 etch stop layer
9-1 SiOx film
9-2 SiNx film

1. A thin film transistor comprising a gate electrode, a gate insulating film, an oxide semiconductor thin film, an etch stop layer for protecting the oxide semiconductor thin film, a source/drain electrode, and a passivation film on a substrate in this order,
wherein the oxide semiconductor thin film is formed of an oxide constituted by metal elements of In, Ga, and Sn and O and has an amorphous structure, and an atomic ratio of each of the metal elements relative to all the In, Ga, and Sn satisfies formulae (1) to (3) below, and
at least one of the etch stop layer and the passivation film contains SiNx.
0.30≦In/(In+Ga+Sn)≦0.50 (1)
0.20≦Ga/(In+Ga+Sn)≦0.30 (2)
0.25≦Sn/(In+Ga+Sn)≦0.45 (3)

2. The thin film transistor according to claim 1, wherein at least part of the oxide semiconductor thin film is crystallized.

3. The thin film transistor according to claim 1, wherein the passivation film contains SiNx, and both ends of the oxide semiconductor thin film in a channel length direction and in a channel width direction are in contact with the etch stop layer.

4. The thin film transistor according to claim 2, wherein the passivation film contains SiNx, and both ends of the oxide semiconductor thin film in a channel length direction and in a channel width direction are in contact with the etch stop layer.
